(19) United States
(12) Patent Application Publication
(10) Pub. No.: US 2024/0288683 A1
(43) Pub. Date: Aug. 29, 2024

(54) MICROSCANNER HAVING MEANDER SPRING-BASED MIRROR SUSPENSION

(71) Applicant: OQMENTED GMBH, Itzehoe (DE)

(72) Inventors: Ulrich HOFMANN, Itzehoe (DE); Fabian SCHWARZ, Itzehoe (DE); Thomas VON WANTOCH, Kiel (DE)

(21) Appl. No.: 18/571,532

(22) PCT Filed: Jun. 21, 2022
(86) PCT No.: PCT/EP2022/066891

§ 371 Date: Dec. 18, 2023

(30) Foreign Application Priority Data
Jun. 22, 2021 (DE) 10 2021 116 121.5

(51) Int. Cl. G02B 26/10; B81B 3/00; G02B 26/08

(52) U.S. Cl. CPC G02B 26/105; B81B 3/0043; G02B 26/0833; B81B 2201/032; B81B 2201/042; B81B 2203/0163; B81B 2203/058

(57) ABSTRACT

A microscanner for projecting electromagnetic radiation onto an observation field comprises: a deflection element having a mirror surface designed as a micromirror for deflecting an incident electromagnetic beam; a support structure that surrounds the deflection element at least in some sections; and a spring device having a plurality of springs. By means of the springs, the deflection element is suspended on the support structure in an oscillating manner in such a way that it can simultaneously carry out a first rotational oscillation around a first oscillation axis and a second rotational oscillation around a second oscillation axis orthogonal thereto relative to the support structure, in order to be able to effectuate a Lissajous projection in an observation field by reflection of an electromagnetic beam incident on the deflection element during the simultaneous oscillations. At least one of the springs comprises a spring section which is designed as a meander spring having a sequence of two or more meanders which follow one another along its longitudinal direction and extend transversely thereto. The spring section is arranged within a space between the deflection element and the support structure and is guided with its longitudinal direction along a line which deviates from a radial direction in relation to the geometric center point of the micromirror.

The present invention relates to a microscanner for the projection, in particular for the Lissajous projection, of electromagnetic radiation onto an observation field and to a beam deflection system equipped with such a microscanner for the projection of image sequences, in particular image sequences having a specific constant image repetition frequency.

Microscanners, which are also referred to in the technical language in particular as “MEMS scanners”, “MEMS mirrors”, or “micromirrors”, or in English in particular as “microscanner” or “micro-scanning mirror” or “MEMS mirror”, are micro-electro-mechanical systems (MEMS) or more specifically micro-opto-electro-mechanical systems (MOEMS) from the class of micro-mirror actuators for dynamic modulation of electromagnetic radiation, in particular of visible light. Depending on the design, the modulating movement of an individual mirror can be translational or rotational around at least one axis. In the first case, a phase-shifting effect is achieved, and in the second case, the deflection of the incident electromagnetic radiation is achieved. Below, microscanners will be considered in which the modulating movement of an individual mirror is rotational. In microscanners, the modulation is generated via a single mirror, in contrast to mirror arrays, in which the modulation of incident light occurs via the interaction of multiple mirrors.

Microscanners may be used in particular to deflect electromagnetic radiation in order to modulate an electromagnetic beam incident thereon with respect to its direction by means of a deflecting element (“mirror”). This can be used in particular to effectuate a Lissajous projection of the beam into an observation field or projection field. For example, imaging sensory objects can be achieved or display functionalities can be implemented. In addition, such microscanners can also be used to irradiate materials in an advantageous manner and thus also process them. Possible other applications are in the area of lighting or illuminating certain open or closed spaces or areas of space using electromagnetic radiation, for example in the context of headlight applications.

In many cases, microscanners consist of a mirror plate (deflection plate) that is suspended laterally on elastically stretchable springs. A distinction is made between single-axis mirrors, which are preferably only to be suspended to be movable around a single axis, from two-axis and multi-axis mirrors.

Both in the case of imaging sensors and in the case of a display function, a microscanner is used to deflect electromagnetic radiation such as a laser beam or a shaped beam from any other source of electromagnetic radiation at least two-dimensionally, for example horizontally and vertically, in order to thus scan or illuminate an object surface within an observation field. In particular, this can be done in such a way that the scanned laser beam sweeps over a rectangular area on a projection surface in the projection field. In these applications, microscanners having at least two-axis mirrors or single-axis mirrors connected in succession in the optical path are used. The wavelength range of the radiation to be deflected can in principle be selected from the entire spectrum from short-wave UV radiation, through the VIS range, NIR range, IR range, FIR range to long-wave terrestrial and radar radiation.

Microscanners are often manufactured using methods of silicon technology. Based on silicon wafer substrates, layer deposition, photolithography, and etching techniques are used to form microstructures in the silicon and thus implement microscanners having movable MEMS mirrors, in particular as a chip. Other semiconductor materials are also possible instead of silicon.

Electrostatic, electromagnetic, piezoelectric, thermal, and other actuator principles are typically used as drives. The mirror movement can in particular be quasi-static (=non-resonant) or resonant, the latter in particular in order to achieve greater oscillation amplitudes, greater deflections, and higher optical resolutions. In addition, in resonant operation, energy consumption can generally be minimized or advantages can be achieved, particularly in terms of stability, robustness, manufacturing yield, etc. Scan frequencies from 0 Hz (quasi-static) to over 100 kHz (resonant) are typical.

Although the microscanners according to the invention described here can in principle be used reasonably and successfully in many different areas, their application in the area of laser projection displays will be discussed in particular hereinafter.

In many known cases, microscanner-based laser projection displays are so-called raster scan displays, in which a first beam deflection axis is operated at high frequency in resonance (typically 15 kHz to 30 kHz) (fast axis) to generate the horizontal deflection and a second axis is operated quasi-statically at low frequency (typically 30 Hz to 60 Hz) to generate the vertical deflection. A fixed grid-like line pattern (trajectory) is typically reproduced 30 to 60 times per second.

A different approach is used in the so-called Lissajous microscanners, in particular also in Lissajous scan displays. There, both axes are usually operated in resonance and a scan path in the form of a Lissajous figure is created. In this way, large amplitudes can be achieved in both axes. The vertical deflection in particular can therefore be very much greater than with a raster scanner. Accordingly, with a Lissajous microscanner, in particular a Lissajous scan display, a significantly higher optical resolution can usually be achieved than with a raster scan display, especially in the vertical direction.

From EP 2 514 211 B1, a deflection device for a projection system for projecting Lissajous figures onto an observation field is known, which is designed to deflect a light beam around at least a first and a second deflection axis to generate the Lissajous figures.

One or more of the following requirements are typically placed on a microscanner-based Lissajous laser beam deflection system:
high scanning frequencies, for example between a minimum of 10 kHz and a maximum of 80 kHz, in order in particular to be able to project as many lines per second as possible and to be able to implement high trajectory repetition rates and, based thereon, high image repetition rates.
Preferably, both beam deflection axes (oscillation axes) are not to differ too much in terms of their scanning frequencies and are therefore to represent two fast axes, in order in particular to achieve very favorable trajectories, good and very fast coverage of the projection area and, in the case of displays, to generate as few as possible or only slightly pronounced flickering artifacts for the observer. The terms “fast” and “slow” in relation to a particular (oscillation) axis refer here to the oscillation frequency with which the deflection element (mirror) of the microscanner oscillates around an associated axis during its operation. In particular, the terms are used relatively to distinguish a “faster” axis from a “slower” axis. Frequency ratios that are close to an integer ratio of the frequency f₁ of the faster axis to the frequency f₂ of the slower axis are always advantageous, so that the ratio f₁/f₂ is, for example, close to 1, 2, 3, 4, etc. The detuning of the respective frequency in relation to the integer ratio plays a major role, because this detuning of the frequency determines how quickly the Lissajous trajectory continues to move spatially. With an integer ratio, the detuning is zero and the trajectory is stationary and constantly reproduces itself in this form. At a detuning of the frequency greater than zero, in contrast, the trajectory begins to travel, specifically within a certain interval the faster the greater the detuning of the frequency is in relation to the integer ratio. The speed of progress at which the trajectory continues to move can advantageously be chosen so that a specific trajectory repetition rate of, for example, 30 Hz, 40 Hz, . . . 100 Hz is established, with which the trajectory reproduces or—more precisely—reproduces under ideal undisturbed conditions. (For explanation: Due to the intervention of phase-locked loops and other control loops, exact reproduction is often not possible. Nevertheless, the advantages of a well-chosen detuning and an accompanying favorable speed of progress of the trajectory remain);
large mirror diameters, in particular to be able to implement small spot sizes and high optical pixel resolution. Especially in conjunction with optical wave guides, large mirror diameters are of great advantage, so that a large so-called “eyebox” and low diffractive losses and as few artifacts as possible can be achieved;
large beam deflection angles, in particular to enable the highest possible pixel resolution and a large projection or observation field (field-of-view, FoV);
the smallest possible installation space or small chip size, in particular to enable the microscanner-based laser projector of electronic devices, for example smart glasses (e.g. augmented reality (AR) glasses), smartphones, or tablet computers, to be able to disappear nearly invisibly into the glass's earpieces or into the housing of the smartphone or tablet, but at the same time also to enable low production costs,
minimal power consumption, in particular to ensure low heat generation from the end device and the longest possible battery life.

However, these are often opposing requirements, as the following examples show:
A microscanner which is reduced in its size in order to be able to better serve compactness requirements usually loses actuator area, thus driving force or torque and thus maximum deflection and thus in particular (pixel) resolution and performance (e.g., image field size, achievable trajectory repetition rate, and the resulting usable image repetition rate).
A microscanner that is reduced in size usually loses the area available for accommodating spring suspensions. This increases the stress in the suspensions and reduces the mechanical deflection and thus also the optical resolution and performance.
A microscanner whose power consumption is reduced in favor of a longer functional life of a mobile device or an application running thereon usually loses drive power or torque, and therefore resolution and performance.
A mirror plate that is enlarged for reasons of smaller spots and therefore higher optical resolution usually increases in mass and moment of inertia and therefore reduces the achievable dynamics and speed.
A mirror plate that is enlarged for reasons of higher optical resolution usually thus displays larger dynamic deformations, which increases the beam divergence and the spot size and partially reduces the resolution.
A spring suspension that is stiffened in favor of higher scanning speeds and higher trajectory repetition rates generally achieves smaller deflections and therefore reduces the achievable optical resolution.

Overall, the design of microscanners generally results in challenging optimization problems, the solution of which often requires taking into consideration not only one or more of the above-mentioned parameters, but also many other properties and boundary conditions. Such additional properties and boundary conditions can in particular affect the manufacturability, manufacturing costs, yield, electronic controllability, reproducibility, available modulation bandwidth of laser sources and drivers, and much more.

The present invention is based on the object of providing an improved, at least two-axis, in particular resonantly operable, microscanner for the Lissajous figure-shaped scanning of an observation field or (equivalently) projection field, which enables an improvement with regard to at least one of the above-mentioned problems.

This object is achieved according to the teaching of the independent claims. Various embodiments and developments of the invention are the subject matter of the dependent claims.

A first aspect of the invention relates to a microscanner for projecting electromagnetic radiation onto an observation field. The microscanner comprises: (i) a deflection element, in particular a mirror plate, having a mirror surface designed as a micromirror for deflecting an incident electromagnetic beam; (ii) a support structure that surrounds the deflection element at least in some sections; and (iii) a spring device having a plurality of springs. By means of the springs, the deflection element is suspended on the support structure in an oscillating manner in such a way that it can simultaneously carry out a first rotational oscillation around a first oscillation axis and a second rotational oscillation around a second oscillation axis orthogonal thereto relative to the support structure, in order to be able to effectuate a Lissajous projection in an observation field by reflection of an electromagnetic beam incident on the deflection element during the simultaneous oscillations. At least one of the springs comprises a spring section which is designed as a meander spring having a sequence of two or more meanders which follow one another along its longitudinal direction and extend transversely thereto. The spring section, in particular when the deflection element is in its rest position, is arranged within a space between the deflection element and the support structure and is guided with its longitudinal direction along a line, which is in particular curved and which deviates from a radial direction in relation to the geometric center point of the micromirror.

Each of the two oscillations can be carried out individually, in particular resonantly, i.e., as an oscillation at a natural frequency of the microscanner with respect to the associated oscillation axis. Both oscillations can also occur simultaneously at their respective natural frequency (so-called “double-resonant” or “double-axis-resonant” operation).

In particular, a “spring” as defined in the invention is understood as an elastic body, in particular a machine element, for absorbing and storing mechanical (potential) energy, which deliberately deforms under load in the load range below an elasticity limit and, when released, resumes its original form.

A “deflection element” as defined in the invention is understood in particular as a body which has a reflective surface (mirror surface) that is smooth enough that reflected electromagnetic radiation, such as visible light, retains its parallelism under the law of reflection and a picture can thus result. The roughness of the mirror surface has to be less than approximately half the wavelength of the electromagnetic radiation for this purpose. The deflection element can in particular be designed as a mirror plate having at least one mirror surface or can comprise such a mirror plate. In particular, the mirror surface itself can consist of a different material, for example of a metal, which is in particular deposited, than the other body of the deflection element.

An “axis of oscillation” or “axis” as defined in the invention is to be understood in particular as an axis of rotation of a rotational movement. It is a straight line that defines or describes a rotation or turn.

A “Lissajous projection” as defined in the invention is to be understood in particular as scanning of an observation field with the aid of electromagnetic radiation, which is effectuated by at least two orthogonal oscillations, which are at least essentially sinusoidal, of a deflection element that deflects the radiation into the field of observation.

As possibly used herein, the terms “comprises,” “contains,” “involves,” “includes,” “has,” “having,” or any other variant thereof are intended to cover non-exclusive inclusion. For example, a method or a device that comprises or has a list of elements is not necessarily restricted to these elements but may involve other elements that are not expressly listed or that are inherent to such a method or such a device.

Furthermore, unless expressly stated to the contrary, “or” refers to an inclusive or and not to an exclusive “or”. For example, a condition A or B is met by one of the following conditions: A is true (or present) and B is false (or absent), A is false (or absent) and B is true (or present), and both A and B are true (or present).

The terms “a” or “an” as possibly used herein, are defined in the meaning of “one or more”. The terms “another” and “a further” and any other variant thereof are to be understood to mean “at least one other”.

The term “plurality” as possibly used herein is to be understood to mean “two or more”.

The term “configured” or “set up” to perform a specific function (and respective modifications thereof) is to be understood in the meaning of the invention that the corresponding device is already provided in a design or setting in which it can execute the function or it is at least settable—i.e., configurable—so that it can execute the function after corresponding setting. The configuration can take place, for example, via a corresponding setting of parameters of a process course or of switches or the like for activating or deactivating functionalities or settings. In particular, the device can have multiple predetermined configurations or operating modes, so that the configuration can be carried out by selecting one of these configurations or operating modes.

A microscanner according to the first aspect makes it possible in particular, on the one hand, to implement large optical scanning angles and high scanning frequencies and, on the other hand, to keep the space or area required for the microscanner small.

In particular, exemplary embodiments of such microscanners are possible which for double-resonant Lissajous operation at mirror diameters of circular or ring-shaped micromirrors between 0.5 mm and 30 mm, on the one hand, have large optical scanning angles in the range of at least 20° and, for example, up to 90°, and on the other hand, permit scanning frequencies between 2 kHz and 90 kHz to be achieved and, for cost reasons, do not require more (chip) edge length than approximately twice or three times the mirror diameter. This also opens up wide use in a wide variety of possible applications, for example relating to installing the microscanner in a mobile consumer end product, such as a smartphone, a portable computer, or even a so-called “wearable” device (such as a “Smart Watch”).

Further preferred embodiments of the microscanner are described hereinafter, which in each case, unless expressly excluded or technically impossible, can be combined as desired with one another and with the further described other aspects of the invention.

In some embodiments, one of the meanders has a first and a second linear meander leg, each extending along a respective radial direction relative to the geometric center point of the micromirror, and a third meander leg, which connects the first meander leg and the second meander leg and at the same time completes the meander. This preferably even applies to all meanders of the spring section. Such a meander geometry represents a very space-saving design of the springs in particular when the longitudinal direction of the spring section, relative to the center point of the micromirror, extends azimuthal (i.e., orthogonal to the radial directions intersecting in this case) or at least predominantly azimuthal. This is especially true if the deflection element has a circumference in the form of an arc, in particular a circular arc.

In some of these embodiments, the first meander leg and the second meander leg each have a specific structure width in the azimuthal direction relative to the center point of the micromirror, which is in the range of a minimum of 0.05° and a maximum of 5.00° or extends therein. It has been found that with this dimensioning of the meander geometry and the spring stiffness dependent thereon, a particularly favorable compromise can be achieved with regard to achieving, on the one hand, large optical scanning angles and high scanning frequencies with a small space or area requirement.

In some of the above-mentioned embodiments, the third meander leg is guided in an arc along the azimuthal direction. This can also advantageously be used for optimizing, in particular minimizing, the space or area required for the spring(s) or their (respective) meander spring-shaped spring section(s) while at the same time ensuring their desired spring properties (particularly with regard to scanning angles, scanning frequencies, resolution, etc.).

In some embodiments, the deflection element has a curved circumferential section, in particular in the form of a circular arc, and the spring section is guided along its longitudinal extension at least in sections parallel to the course of this circumferential section of the deflection element. The respective meander-shaped spring sections of all of the springs preferably extend at least in sections parallel to the course of the circumference of the deflection element. These embodiments can also be used particularly advantageously to keep the space or area required for the springs with the desired spring properties low, in particular minimal.

In some of these embodiments, the circumference of the deflection element extends in the shape of a circular arc at least in one circumferential section and the spring section is guided with its longitudinal direction along a line which extends at least in sections parallel to the circular arc-shaped course of this circumferential section of the deflection element.

In particular, the circumference of the deflection element can be circular overall. These embodiments are particularly space-saving or area-saving solutions In some embodiments, at least two of the following functional elements of the microscanner are at least partially manufactured from the same plate-shaped substrate: the spring device, the deflection element, the support structure. In particular, the substrate can be a semiconductor substrate, such as a silicon substrate, from which at least two, preferably all, of the aforementioned functional elements are manufactured. On the one hand, this has the advantage that the microscanner, or the functional elements mentioned thereof, can be produced within the scope of the same substrate processing, instead of being initially produced as separate components in separate processes and subsequently assembled to form microscanners. On the other hand, in particular the production of the microscanner or the functional elements mentioned from a single substrate allows a particularly space-efficient or surface-efficient solution, since here production processes known from semiconductor or microsystem technology can be used, which in particular allow the deliberate production of ultrasmall structures.

In some embodiments, the number of springs of the spring device is 2, 3, 4, 5, or 6. On the one hand, this is advantageous in that such a limited number of springs is still compatible with the requirement of a particularly space-saving or area-saving microscanner design, on the other hand, however, the formation of the two orthogonal oscillation axes with sufficiently high scanning frequencies (in particular resonance frequencies) is also possible. An even number of springs can be used in particular to define a frequency-independent fixed position of the two oscillation axes a priori, while an odd number of springs can be used particularly advantageously when it is important that the resonance frequencies of both oscillation axes correspond.

In some embodiments, the microscanner furthermore comprises a drive device for directly or indirectly driving the oscillations of the microscanner around the two oscillation axes. In particular, electrostatic, piezoelectric, electromagnetic, and thermal drives come into consideration as drives, which can already be entirely or partially provided and manufactured in the context of MEMS manufacturing at wafer level. In addition, so-called external drives are also possible, which supply the component with oscillation energy in the appropriate frequency range from an external non-MEMS actuator, such that the MEMS mirror begins to oscillate in one or both axes.

In particular, the drive device according to some of these embodiments can comprise at least one drive element having a piezo actuator which is arranged on one of the springs in order to set it into oscillation. This represents a particularly space-saving and moreover, due to the direct coupling of the piezo actuator with the spring, particularly effective and, in particular, energy-efficient possibility for implementing a drive device for the microscanner.

In some embodiments, the drive device is configured so that it can set the deflection element into a double-resonant oscillation with respect to the first and second oscillation axes. For this purpose, the actuator system can in particular comprise or consist of one or more actuators.

In some embodiments, the drive device is configured in such a way that it can set the deflection element into a double-resonant oscillation with respect to the first and second oscillation axes in such a way that for the frequency ratio of the oscillation frequency f₁ with respect to the faster of the two oscillation axes to the oscillation frequency f₂ with respect to the slower of the two oscillation axes, the following applies: f₁/f₂=F+v, wherein F is a natural number (F=1, 2, 3, . . . ) and the following applies to the detuning v: v=(f₁−f₂)/f₂ with (f₁−f₂)<200 Hz, wherein v is not an integer. This results here in a frequency ratio f₁/f₂ close to 1, 2, 3, or 4, etc.

The detuning v can in particular be achieved in such a way that only one of the two oscillation frequencies or both differ or differ from the respective resonance frequency for the associated oscillation axis. The detuning v in relation to an integer frequency ratio plays a major role here, because this detuning of the frequency determines how quickly the Lissajous trajectory continues to move spatially. With an integer ratio, the detuning is zero and the trajectory is stationary and constantly reproduces itself in this form.

At a noninteger detuning v>0, in contrast, the trajectory begins to travel, specifically within a certain interval the faster the greater the detuning v is in relation to the integer ratio. The speed of progress at which the trajectory continues to move can advantageously be chosen so that a specific trajectory repetition rate (complete phase passages/time), for example from the frequency range 30 Hz to 100 Hz is established, with which the trajectory reproduces or reproduces under ideal undisturbed conditions. (For explanation: Exact reproduction is often not possible, especially when using phase-locked loops or other control loops. Nevertheless, the advantages of a well-chosen detuning and an accompanying favorable speed of progress of the trajectory remain). On the basis of a detuning v selected in this way, in particular an improved, i.e., increased line density, at least on average over time, can also be achieved.

In some embodiments, the microscanner is designed so that the deflection element can simultaneously oscillate freely around both mutually orthogonal oscillation axes at a respective axis-specific individual resonance frequency. This can be used in particular to configure the microscanner for Lissajous projections having two “fast” (high-frequency) oscillation axes, the resonance frequencies of which are close to one another but do not form an exact integer ratio. In such cases, a Lissajous trajectory results in the observation field, or on an object surface (for example projection screen) lying in the observation field transversely to the optical axis of the projection, which fills or illuminates the image field in a very short time, in particular in the context of a digital image of each pixel of the image field. The time span required for this is largely determined by the choice of resonance frequencies.

In particular, according to some of these embodiments, the ratio of the larger of the resonance frequencies of the first and second oscillations to the smaller of these oscillations can correspond to an integer value or deviate by at most 10%, preferably by at most 5%, from the ratio of the closest integer value.

In some embodiments, the spring device, in particular for the purpose of forming oscillation axes of different speeds, has an even number N of identical springs for suspending the deflection element on the support structure, the overall arrangement of which, however, is selected deviating from an N-fold rotational symmetry with respect to an axis of symmetry orthogonal to both oscillation axes such that the resulting spring stiffness of the spring device caused overall by the N springs and/or the effective moment of inertia of the oscillatory arrangement of the deflection element together with the springs is different for the two oscillation axes. For example, the two oscillation axes can be detuned if four identical springs are allowed to engage on a circularly symmetrical micromirror (for example, mirror plate) and the selected distances between the adjacent springs are not exactly the same.

In some other embodiments, the number N of springs by means of which the deflector is suspended from the support structure is even. The overall arrangement of the N springs has an N-fold rotational symmetry with respect to an axis of symmetry that is orthogonal to both axes of oscillation. In addition, the respective spring width profiles of the N springs are selected differently along their respective course (i.e., in particular along the meandering course of the spring body itself) or their respective longitudinal extent in such a way that N/2 of the springs have a first spring width profile (spring width as a function of the position under consideration along the longitudinal direction of the spring section) and the other N/2 springs each have a different corresponding second spring width profile, so that the resulting spring stiffness of the spring device caused by the N springs overall and/or the effective moment of inertia of the oscillatory arrangement of the deflection element together with the springs for the two axes of oscillation are different.

Further advantages, features, and possible applications of the present invention result from the following more detailed description in conjunction with the figures.

In the figures:

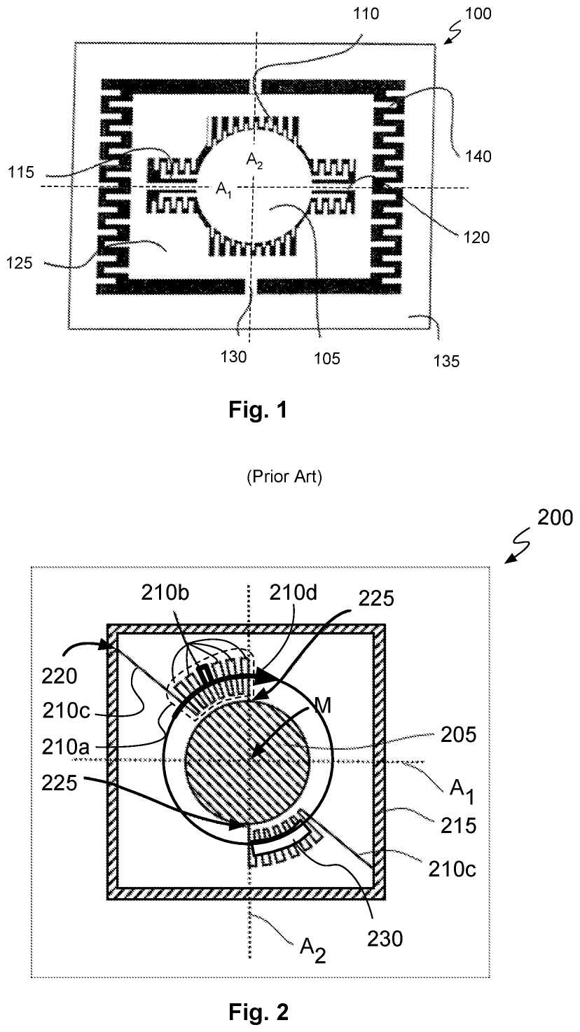

FIG. 1 schematically shows a top view of a two-axis, gimbal-suspended (i.e., with gimbal) micromirror having comb drives according to a microscanner architecture known from EP 2 514 211 B1;

FIG. 2 shows a schematic top view of a micromirror suspended without gimbal according to an embodiment of the present invention having two meander springs;

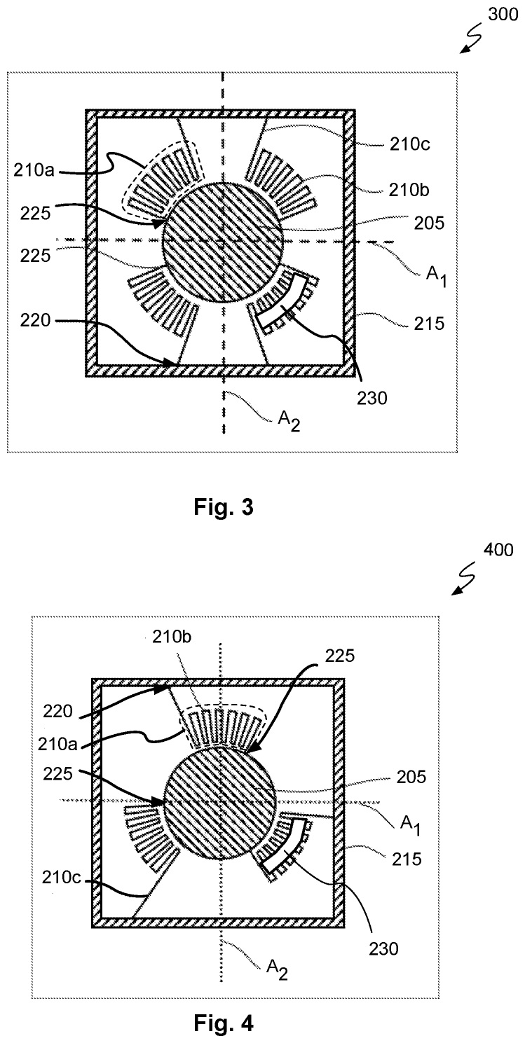

FIG. 3 shows a schematic top view of a micromirror suspended without gimbal according to another embodiment of the present invention having four meander springs;

FIG. 4 shows a schematic top view of a micromirror suspended without gimbal according to still another embodiment of the present invention having three meander springs; and

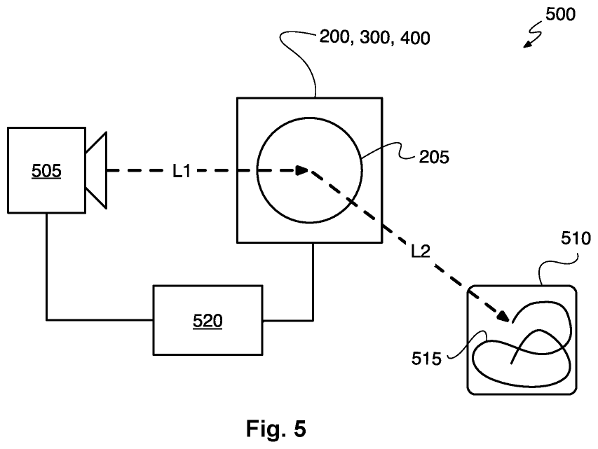

FIG. 5 schematically shows an exemplary beam deflection system having a microscanner according to an exemplary embodiment of the present invention.

First of all, with reference to FIG. 1, a microscanner architecture known from the prior art will now be briefly described with regard to its mirror suspension in order to provide a brief overview of a technical starting point from which the present invention proceeds.

FIG. 1 shows a schematic top view of a microscanner architecture 100 known from EP 2 514 211 B1 having a two-axis (orthogonal oscillation axes A₁ and A₂), gimbal-suspended micromirror 105 (mirror plate). Electrostatic comb drives 110 remote from the axis and comb drives 115 close to the axis are also shown, which can also be used as sensor electrodes. The mirror plate 105 is suspended via internal torsion springs 120 in a movable frame 125, which is suspended in a fixed chip frame 135 by external torsion springs 130. The frame 125 can be caused to resonate by electrostatic comb drives 140, wherein comb electrodes that are also present near the axis for driving or sensor purposes of the movable frame 125 have been omitted for the sake of clarity. The oscillation axes A1 and A2 shown were added to the figure taken from EP 2 514 211 B1 (cf. FIG. 3 there) for better illustration and the reference numbers were adapted.

Various exemplary embodiments of microscanner architectures according to the invention will now be explained below with reference to FIGS. 2 to 4. Throughout FIGS. 2 to 4, the same reference numbers are used for the same or corresponding elements of the invention.

FIG. 2 shows a first exemplary embodiment 200 of a two-axis microscanner according to the invention. The microscanner 200 comprises a circular mirror plate as a deflection element 205, which is suspended via a spring device with a plurality N of springs (here N=2, for example) springs 210 on a frame 215 which is used as a support structure and surrounds the deflection element 205 and the springs 210. The frame 215 advantageously has, in particular, a higher torsional and bending rigidity than the springs 210. In particular, it can be manufactured as a rigid chip frame made of a semiconductor substrate, such as silicon. Each of the springs 210 extends here between an assigned starting point 220 on the frame 215 on the one hand and an assigned coupling point 225 on the deflection element 205. By means of the springs 210, the deflection element is suspended on the support structure 215 in an oscillating manner in such a way that it can simultaneously carry out a first rotational oscillation around a first oscillation axis A₁ and a second rotational oscillation around a second oscillation axis A₂ orthogonal thereto relative to the support structure, in order to be able to effectuate a Lissajous projection in an observation field (645) by reflection of an electromagnetic beam (L₁) incident on the deflection element during the simultaneous oscillations. The two oscillations can in particular be individually resonant or double resonant together.

Each of the springs 210 comprises a spring section 210a, which is designed as a meander spring having a sequence of multiple meanders 210b which follow one another along its longitudinal direction (located in the middle of the spring) and extend transversely thereto. The spring section 210a is arranged within a space between the deflection element 205 and the support structure or the frame 215 and is guided with its longitudinal direction 210d along a line, which is in particular in the form of a circular arc and which extends deviating from a radial direction in relation to the geometric center point M of the deflection element or micromirror 205. The circular arc defines in particular an azimuthal direction (in polar coordinates) relative to the center point M.

In particular, the term “meander” 210b is understood here as a loop in the structure of the meander spring, which extends in a loop shape between two intersection points, successive along the longitudinal direction 210d of the meander spring, of the spring with the spring center line (here coinciding with the line 210d). Only for the purpose of illustration, one of the meanders is drawn thicker than the others in FIG. 2, although the widths of the meanders in this exemplary embodiment actually do not have to or are not supposed to differ from one another. The respective segments of a meander 210b extending in a radial direction preferably have (lateral) structure widths of at least 0.05° and at most 5° per radially extending meander member, which are also arranged along circular arcs around the mirror plate 205. Each spring section 210a is coupled to the frame 215 on the frame side via a spring bar 210c belonging to the respective spring 210, which can extend in particular in a radial direction relative to the geometric center point M of the micromirror 205.

Overall, with the microscanner architecture illustrated in FIG. 2, on the one hand, a very large spring length can be achieved and at the same time a very space-saving design can be implemented (the same also applies to the other microscanner architectures shown in FIGS. 3 and 4).

Electrostatic, piezoelectric, electromagnetic, and thermal drives come into consideration as drives, which can in particular already be entirely or partially provided and manufactured in the context of MEMS manufacturing at wafer level. In addition, so-called external drives are also possible, which supply the component with oscillation energy in the appropriate frequency range from an external non-MEMS actuator, such that the deflection element begins to oscillate in one or both axes. Piezoelectric actuators can be particularly advantageously accommodated on the springs 210, (in particular their meander spring sections 210a), where they can efficiently excite the mirror oscillation. In FIG. 2 this is shown as an example for (only) one spring 210 having a piezo actuator 230 arranged thereon. Overall, the drive can in particular be configured so that it drives each of the two oscillation axes A₁ and A₂ at their respective resonance frequency (double-resonant operation). This operating mode can be used advantageously in laser projection displays and imaging sensors such as 3D cameras, LIDAR sensors, OCT devices, etc. as well as in laser material processing.

Lissajous MEMS scanners having two “fast” axes are particularly advantageous, the resonance frequencies of which almost, but not exactly, form an integer ratio. This then results in a Lissajous trajectory that can advantageously efficiently fill the image field in a very short period of time, which can be configured in the design of the microscanner by appropriately defining the resonance frequencies. An advantageous choice is, in particular, to select a frequency ratio of the resonance frequencies of close to 1 and then to set a difference frequency of the actual resonance frequencies for the two oscillator axes A₁ and A₂ so that this difference corresponds to the desired trajectory repetition rate, which advantageously in particular can correspond to the image repetition rate (when projecting image sequences, for example in video projection or sensor operation). For example, the first axis A₁ can be tuned to 10 kHz and the second axis A₂ to 10.2 kHz in order to implement a trajectory repetition rate of 200 Hz.

The two axes A₁ and A₂ can be detuned in a particularly advantageous manner if, as illustrated by way of example in FIG. 3, N=4 identical springs are allowed to act on the mirror plate 205 and the distances between the springs are not selected to be exactly the same. In the exemplary embodiment in FIG. 3, a microscanner 300 is shown in which the distance between the two upper springs (in the figure) is less than the distance between an upper and a lower spring. This results in different overall spring stiffnesses and also different moments of inertia for the two different oscillation axes A₁ and A₂, which results in a shift/splitting of the resonance frequencies despite identical spring geometries. Alternatively, the splitting can also be achieved in particular with identical spring distances, but different spring widths of two of the four springs.

FIG. 4 shows a further embodiment 400 of a microscanner, in which N=3 springs 210 are provided, which—as illustrated—can be arranged in particular rotationally symmetrically around the deflection element 205. The microscanner 400 is particularly advantageous for applications such as projection arrangements in which it is even desired to achieve identical resonance frequencies for both axes A₁ and A₂ in order to completely scan a projection surface in the observation field using circular or elliptical paths or trajectories. To do this, the amplitude of the circular or elliptical path then has to be modulated quickly enough so that the resulting path (trajectory) can reach every location on the projection surface within a predetermined time interval.

FIG. 5 schematically shows a beam deflection system according to an exemplary embodiment 500 of the present invention, which can be used in particular for projecting images or image sequences (e.g., moving images, videos, etc.). The beam deflection system 500 comprises a radiation source 505, which can in particular be a laser source, wherein the wavelength of the emitted radiation L₁ can be in particular in the visible spectral range, although depending on the application, other spectral ranges can also be used, for example in the context of methods for material inspection. In the following, unless otherwise stated, it is assumed by way of example that the radiation L₁ is emitted as a laser beam in the visible spectral range.

The laser beam L₁ is directed at a microscanner according to the invention, in particular according to one of embodiments 200, 300, or 400, as explained above with reference to FIGS. 2 to 4. At the deflection element, in particular the mirror plate, 205, the beam is reflected (mirrored) in the sense of an optical image and directed as a reflected beam L₂ onto a projection surface 510 in the observation field of the microscanner 200, 300, or 400.

The beam deflection system 500 furthermore comprises a control device 520, which is configured to supply the radiation source with at least one modulation signal, depending on which the laser beam is modulated. The modulation can particularly affect its temporal or local intensity profile. However, depending on the type of radiation source, other types of modulation are also conceivable, in particular modulations of the wavelength (for example color) or wavelength distribution of the radiation emitted by the radiation source 505. When projecting images, the modulation accordingly takes place depending on the current deflection direction, so that corresponding image points on the projection surface are generated having the associated pixel value of the corresponding image point of the image to be displayed by modulation.

The control device 520 is furthermore configured to activate a drive device of the microscanner 200, 300, or 400 in order to prompt it to cause the drive of, in particular double-resonant, simultaneous oscillations of the deflection element 205 of the microscanner around its two oscillation axes A₁ and A₂, so that the light or radiation point generated by the reflected beam L₂ on the projection surface 510 passes through a trajectory or path in the form of a Lissajous FIG. 515, which preferably completely illuminates an area on the projection surface intended as an image surface already within a short time interval. In the case of a projection of a digital image made up of pixels, this means that all pixels are reached or displayed by the trajectory in the time interval.

However, the beam deflection system 500 is also operable in the opposite direction, so that radiation emitted or reflected by an object to be observed is scanned by means of a Lissajous figure and in this case reflected on the corresponding oscillating deflection element 205 and imaged in the direction of the unit 505, where a sensor device can then be located, in particular an image sensor, in order to sensorically detect the radiation.

While at least one exemplary embodiment has been described above, it is to be noted that a large number of variations thereto exist. It is also to be noted that the exemplary embodiments described only represent non-limiting examples, and are not intended to restrict the scope, the applicability, or the configuration of the devices and methods described herein. Rather, the preceding description will provide those skilled in the art with guidance for implementing at least one exemplary embodiment, wherein it is apparent that various changes in the operation and arrangement of elements described in an exemplary embodiment may be made without departing from the scope of the subject matter defined in the appended claims and its legal equivalents.

### LIST OF REFERENCE NUMERALS

100 known microscanner architecture having gimbal suspension
105 deflection element, in particular mirror plate
110 comb drive remote from the axis for oscillation axis A₁
115 comb drive close to the axis for oscillation axis A₁
120 internal torsion spring
125 movable frame
130 external torsion spring
135 chip frame
140 external comb drive for oscillation axis A₂
200 microscanner architecture according to an embodiment having 2 springs
205 deflection element, in particular mirror plate
210 spring
210a meander spring-shaped spring section
210b individual meander(s)
210c spring bar
210d longitudinal direction of the spring section 210a
215 frame-shaped support structure, chip frame
220 outer end of the respective spring, starting point on the chip frame 215
225 inner end of the respective spring, coupling point on the deflection element
230 drive device, in particular piezo actuator
300 microscanner architecture according to another embodiment having 4 springs
400 microscanner architecture according to still another embodiment having 3 springs
500 beam deflection system 500
505 radiation source, in particular laser, alternatively, (in sensor operation) sensor device
510 projection surface in the observation field
515 Lissajous FIG.
520 control device
A₁ first (oscillation) axis
A₂ second (oscillation) axis
L₁ beam incident on microscanner
L₂ beam reflected by the microscanner
M geometric center point M of the micromirror 205

What is claimed is:

1. A microscanner for projecting electromagnetic radiation onto an observation field, wherein the microscanner comprises:
a deflection element having a mirror surface designed as a micromirror for deflecting an incident electromagnetic beam;
a support structure laterally adjacent at least in sections to the deflection element in its idle position; and
a spring device having a plurality of springs, by means of which the deflection element is suspended on the support structure in an oscillating manner in such a way that it can simultaneously carry out a first rotational oscillation around a first oscillation axis and a second rotational oscillation around a second oscillation axis orthogonal thereto relative to the support structure, in order to be able to effectuate a Lissajous projection in an observation field by reflection of an electromagnetic beam incident on the deflection element during the simultaneous oscillations;
wherein at least one of the springs comprises a spring section which is designed as a meander spring having a sequence of two or more meanders which follow one another along its longitudinal direction and extend transversely thereto; and
wherein the spring section is arranged within a space between the deflection element and the support structure and is guided with its longitudinal direction along a line which extends deviating from a radial direction in relation to the geometric center point of the micromirror.

2. The microscanner according to claim 1, wherein one of the meanders comprises a first and a second linear meander leg, each extending along a respective radial direction relative to the geometric center point of the micromirror, and a third meander leg, which connects the first meander leg and the second meander leg and at the same time completes the meander.

3. The microscanner according to claim 2, wherein the first meander leg and the second meander leg each have a structure width determined in the azimuthal direction relative to the center point of the micromirror, which is in the range of a minimum of 0.05° and a maximum of 5.00° or extends therein.

4. The microscanner according to claim 2, wherein the third meander leg is guided in an arc shape along the azimuthal direction.

5. The microscanner according to claim 1, wherein the deflection element comprises a curved circumferential section and the spring section is guided along its longitudinal extent at least in sections parallel to the course of this circumferential section of the deflection element (205).

6. The microscanner according to claim 5, wherein the circumference of the deflection element extends in the shape of a circular arc at least in a circumferential section and the spring section is guided with its longitudinal direction along a line which is at least partially parallel to the circular arc-shaped course of this peripheral section of the deflection element.

7. The microscanner according to claim 1, wherein at least two of the following functional elements of the microscanner are at least partially manufactured from the same plate-shaped substrate: the spring device, the deflection element, the support structure.

8. The microscanner according to claim 1, wherein the number of springs of the spring device is 2, 3, 4, 5, or 6.

9. The microscanner according to claim 1, furthermore comprising a drive device for directly or indirectly driving the oscillations of the microscanner around the two oscillation axes.

10. The microscanner according to claim 9, wherein the drive device comprises at least one drive element having a piezo actuator which is arranged on one of the springs in order to cause it to oscillate.

11. The microscanner according to claim 9, wherein the drive means is configured so that it can cause the deflection element to undergo double-resonant oscillation with respect to the first and second oscillation axes.

12. The microscanner according to claim 11, wherein the drive device is configured in such a way that it can cause the deflection element to undergo double-resonant oscillation with respect to the first and second oscillation axes in such a way that the following applies to the frequency ratio of the oscillation frequency f₁ with respect to the faster of the two oscillation axes to the oscillation frequency f₂ with respect to the slower of the two oscillation axes: f₁/f₂=F+v, wherein F is a natural number and the following applies to the detuning v: v=(f₁−f₂)/f₂ with (f₁−f₂)<200 Hz, wherein v is not an integer.

13. The microscanner according to claim 1, which is designed such that the deflection element can simultaneously oscillate freely around both mutually orthogonal oscillation axes at a respective axis-specific individual resonance frequency.

14. The microscanner according to claim 13, wherein the ratio of the greater of the resonance frequencies of the first and second oscillations to the lesser of these oscillations corresponds to an integer value or deviates by at most 10%, preferably at most 5%, from the integer value closest to the ratio.

15. The microscanner according to claim 13, wherein the spring device for suspension of the deflection element on the support structure has an even number N of identical springs, but their overall arrangement is selected deviating from an N-fold rotational symmetry with respect to an axis of symmetry orthogonal to both oscillation axes so that the resulting overall spring stiffness of the spring device caused by the N springs and/or the effective moment of inertia of the oscillatory arrangement of the deflection element in addition to the springs differs for the two oscillation axes.

16. The microscanner according to claim 15 wherein:
the number N of springs by means of which the deflection element is suspended from the support structure is even;
the overall arrangement of the N springs has an N-fold rotational symmetry with respect to an axis of symmetry that is orthogonal to both oscillation axes; and
the respective spring width profiles of the N springs, however, are selected differently along their respective course or their respective longitudinal extension in such a way that N/2 of the springs have a first spring width profile and the other N/2 springs each have a corresponding second spring width profile different therefrom, so that the resulting spring stiffness of the spring device caused overall by the N springs and/or the effective moment of inertia of the oscillatory arrangement of the deflection element together with the springs differs for the two oscillation axes.

17. The microscanner according to claim 3, wherein the third meander leg is guided in an arc shape along the azimuthal direction.

18. The microscanner according to claim 2, wherein the deflection element comprises a curved circumferential section and the spring section is guided along its longitudinal extent at least in sections parallel to the course of this circumferential section of the deflection element.

19. The microscanner according to claim 3, wherein the deflection element comprises a curved circumferential section and the spring section is guided along its longitudinal extent at least in sections parallel to the course of this circumferential section of the deflection element.

20. The microscanner according to claim 4, wherein the deflection element comprises a curved circumferential section and the spring section is guided along its longitudinal extent at least in sections parallel to the course of this circumferential section of the deflection element.
